(19) United States
(12) Patent Application Publication
(10) Pub. No.: US 2024/0385236 A1
(43) Pub. Date: Nov. 21, 2024

(54) ELECTRONIC CONTROL UNIT AND METHOD FOR MONITORING SOLDER JOINTS OF AN ELECTRONIC CONTROL UNIT

(71) Applicant: Robert Bosch GmbH, Stuttgart (DE)

(72) Inventors: Steffen Michelberger, Heilbronn (DE); Georg Konstantin, Heilbronn (DE); Hannes-Sebastian Zechlin, Leonberg (DE)

(21) Appl. No.: 18/688,990

(22) PCT Filed: Aug. 30, 2022
(86) PCT No.: PCT/EP2022/074055

§ 371 Date: Mar. 4, 2024

(30) Foreign Application Priority Data
Sep. 8, 2021 (DE) 10 2021 209 892.4

(51) Int. Cl. G01R 31/28

(52) U.S. Cl. CPC G01R 31/2812

(57) ABSTRACT

An electronic control unit. The electronic control unit includes a printed circuit board, a package, and at least one analog-to-digital converter. The package has an electronic circuit and, by means of a plurality of solder joints, is arranged on and electrically coupled to the printed circuit board. The at least one analog-to-digital converter is electrically coupled to at least one solder joint and is designed to generate a measurement signal on the basis of an electrical resistance of the solder joint.

### FIELD

The present invention relates to an electronic control unit and to a method for monitoring at least one solder joint of an electronic control unit.

### BACKGROUND INFORMATION

The use of electronic control units (ECUs) for components in the automotive sector, for example in brake systems, as engine control units or in steering systems, has increased significantly in recent decades due to modern technological trends, such as function extension, automation, electrification of the powertrain, or networked and highly automated driving.

Electronic processor components or integrated circuits (application-specific integrated circuits; ASICs) based on microchips, which are often installed as so-called ball grid arrays (BGAs) or QFN packages (quad flat no leads; QFNs), are a central part of the control units. Electrical contact between the components and the printed circuit board is made via hemispherical or rectangular soldering points that are soldered to the printed circuit board in a reflow soldering process. Depending on the computing power of the processor, a BGA package can be contacted with more than a thousand soldering points.

Transport, operating and environmental stresses on the vehicle, and thus on the control unit, such as vibration and temperature, result in constant stress on the soldering points over the entire service life of the vehicle. Fatigue-induced breaking or cracking of the soldering points can result in total failure of the control unit. Especially in the case of control units in the areas of brake systems and highly autonomous driving, this poses considerable safety risks to the vehicle and its occupants, as well as to uninvolved road users.

### SUMMARY

The present invention provides an electronic control unit and a method for monitoring at least one solder joint of an electronic control unit.

Preferred embodiments of the present invention are disclosed herein.

According to a first aspect, the present invention relates to an electronic control unit. The electronic control unit comprises a printed circuit board, at least one package, and at least one analog-to-digital converter. The package has an electronic circuit and, by means of a plurality of solder joints, is arranged on and electrically coupled to the printed circuit board. According to an example embodiment of the present invention, the at least one analog-to-digital converter is electrically coupled to at least one solder joint and is designed to generate a measurement signal on the basis of an electrical resistance of the at least one electrically coupled solder joint.

According to a second aspect, the present invention relates to a method for monitoring at least one solder joint of an electronic control unit, wherein the electronic control unit has a printed circuit board and a package having an electronic circuit, wherein, by means of a plurality of solder joints, the package is arranged on and electrically coupled to the printed circuit board, and wherein at least one analog-to-digital converter is electrically coupled to at least one solder joint. According to an example embodiment of the present invention, the at least one analog-to-digital converter generates a measurement signal on the basis of an electrical resistance of the at least one solder joint electrically coupled to the analog-to-digital converter. The generated measurement signal is evaluated.

The monitored solder joint forms an electrical resistance via various factors, for example thermal behavior of the control unit and of the printed circuit board, mechanically or thermally induced stress or expansion ratios, aging, printed circuit board material, and solder paste material, which electrical resistance is ascertained by an analog-to-digital converter. The present invention provides an electronic circuit of a control unit, which circuit is designed to monitor solder joints by means of which the package is connected to the printed circuit board. An automated monitoring system for predictive diagnostics (PD) of the electronic control unit can thereby be implemented.

Implementing an early warning system by monitoring the soldering points for possible signs of fatigue or damage can significantly reduce the safety risk. This is relevant in particular to electronic control units used in motor vehicles that are suitable for autonomous driving.

According to a further embodiment of the present invention, the electronic circuit comprises a resistance to which a reference potential is applied. This resistance is connected in series with the electrical resistance of the solder joint. A voltage divider is thus provided.

According to a further embodiment of the present invention, the measurement signal is transmitted to an external evaluation device, which calculates a quality of the solder joint on the basis of the measurement signal. The external evaluation device can be designed to monitor a plurality of control units. The external evaluation device may, for example, be a server connected to the control units. The external evaluation device may also be a further control unit in a motor vehicle that receives and evaluates, for example via a CAN bus, the measurement signal generated by the at least one analog-to-digital converter. According to a further embodiment, the electronic control unit comprises the evaluation device.

According to a further embodiment of the electronic control unit of the present invention, the evaluation device calculates the quality on the basis of a two-stage scale. A first value corresponds to the case that the solder joint is damaged, while the second value corresponds to an intact solder joint.

According to a further embodiment of the electronic control unit of the present invention, the evaluation device calculates the quality on the basis of an at least three-stage scale. The quality can thereby be measured finely. In this way, not only is the destruction detected, but deterioration of the state of the solder joint can already be determined in advance. In this case, a corresponding warning signal can be output in order to indicate an expected failure of the solder joint. In a multi-stage (i.e., at least three-stage) scale, the different states specified by the scale can also correspond to an expected lifetime. The evaluation device can thus be designed to calculate and output the expected lifetime of the respectively monitored solder joints on the basis of the measurement signal generated by the at least one analog-to-digital converter. In this case, the analog-to-digital converter allows the quality of the aging solder joint to be more finely determined, and not only in a binary manner with a digital microcontroller input.

The discrete steps of the scale can be derived according to the voltage resolution of the analog-to-digital converter(s) used. The selection of a particular number of voltage steps, i.e., the associated determination of a lower or an upper voltage threshold, defines the critical range of the beginning solder joint aging. The difference between the upper and lower voltage thresholds defines the tolerance of the evaluation of criticality.

According to a further embodiment of the electronic control unit of the present invention, the evaluation device calculates the quality on the basis of at least one threshold value. For example, the evaluation device can calculate the electrical resistance of the solder joint on the basis of the measurement signal. This electrical resistance is compared to the at least one threshold value. The quality is calculated and output accordingly.

According to a further embodiment of the electronic control unit of the present invention, the evaluation device uses the corresponding evaluation of the quality to make a preliminary estimate of when the monitored solder joint will fail. This preliminary estimate allows a conclusion to be drawn as to when other solder joints are at risk of failure. Thus, for example, for autonomously operating vehicles whose control units are subject to a functionally high automotive safety integration level, ASIL classification, it is possible to predict when the control units will begin to fail and no longer be able to meet their requirement to operate autonomously.

According to a further embodiment of the electronic control unit of the present invention, the solder joints are solder balls or solder pins (for example for BGA or QFN packages).

According to a further embodiment of the electronic control unit of the present invention, the solder joints are arranged on a rectangular base, wherein the at least one analog-to-digital converter is electrically coupled to at least one solder joint in a corner of the rectangular base. In particular, it can be provided that exactly one analog-to-digital converter is electrically coupled to exactly one solder joint in a corner of the rectangular base. The solder joints in the corners are in principle the most critical solder joints since solder joints located at the corners typically experience the greatest mechanical stress in the soldered component and are particularly susceptible to crack formation. Furthermore, it may also be provided that a separate analog-to-digital converter is provided in each case for each solder joint in a corner.

The solder joints in the corner are preferably non-functional. These solder joints are typically connected to redundant GND (usually the electrical ground of the control unit). Thus, if the associated soldering points break or crack due to aging phenomena, no functional damage to the control units results.

According to an example embodiment of the present invention, by monitoring the solder joints in the corners, the control unit is designed to monitor the non-functional and at the same time highly stressed soldering points. This so-called canary feature can trigger a warning message in the event of fatigue or failure of the monitored soldering points. Furthermore, it is also possible to monitor other components or circuits.

According to a further embodiment of the electronic control unit of the present invention, a first analog-to-digital converter is electrically coupled to a first solder joint, and a second analog-to-digital converter is electrically coupled to a second solder joint, wherein the first solder joint and the second solder joint are located on a diagonal of the rectangular base. As a rule, the largest expansions occur along the component diagonal. It can therefore be sufficient to monitor the corners located in a diagonal. The preferred diagonal can be determined by means of a voltage or expansion simulation.

Furthermore, according to an example embodiment of the present invention, it can also be provided that analog-to-digital converters are electrically coupled to more than four solder joints.

According to a further embodiment of the electronic control unit of the present invention, each analog-to-digital converter is connected to exactly one solder joint. If a plurality of solder joints is monitored, a plurality of analog-to-digital converters is accordingly provided. However, it can also be provided that an analog-to-digital converter monitors a plurality of solder joints.

According to a further embodiment of the electronic control unit of the present invention, the electronic circuit is a microcontroller or an application-specific circuit (ASIC).

According to a further embodiment of the electronic control unit of the present invention, the electronic circuit is connected to the plurality of solder joints via an interposer.

### BRIEF DESCRIPTION OF THE DRAWINGS

FIG. 1 is a schematic cross-sectional view of a control unit according to an example embodiment of the present invention.

FIG. 2 is a schematic circuit diagram of a portion of the control unit according to an example embodiment of the present invention.

FIG. 3 is a flowchart of a method for monitoring at least one solder joint of an electronic control unit according to an example embodiment of the present invention.

In all figures, identical or functionally identical elements and devices are provided with the same reference signs. The numbering of method steps serves the purpose of clarity and is generally not intended to imply a specific chronological order. In particular, a plurality of method steps may also be carried out simultaneously.

### DETAILED DESCRIPTION OF EXAMPLE EMBODIMENTS

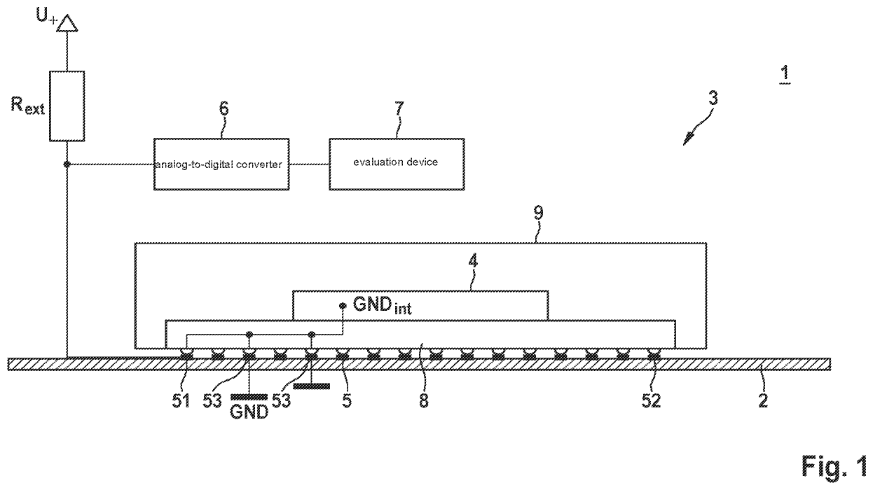

FIG. 1 shows a schematic cross-sectional view of a control unit 1. The control unit 1 comprises a printed circuit board 2, a package 3, and an analog-to-digital converter 6.

The package 3 comprises a housing 9, in which an electronic circuit 4, for example a microcontroller or an application-specific circuit, is located. The electronic circuit 4 is electrically coupled to solder joints 5 via an interposer 8 or so-called bonds, which solder joints are attached to the printed circuit board 2. The solder joints 5 can be solder balls or solder pins. In particular, the package 3 may be a pin grid array (PGA) package or a ball grid array (BGA) package.

The electronic circuit 4 is connected to the internal ground (GNDᵢₙₜ) via the interposer 8 or via solder bonds, which internal ground is in turn ensured by a plurality of solder joints 53 connected to the external ground (GND).

The solder joints 5 are arranged in a rectangular, preferably square, base. The analog-to-digital converter 6 is electrically coupled to a (non-active) solder joint 51 in a corner of the rectangular base and is designed to generate a measurement signal on the basis of an electrical resistance of the monitored solder joint 51.

For this purpose, an external resistance Rₑₓₜ is furthermore connected in parallel, to which external resistance a reference potential U₊ is applied. A voltage divider is thereby formed.

Furthermore, an evaluation device 7 is provided, for example a microcontroller, which receives the measurement signal of the analog-to-digital converter 6. The measurement signal can be the measured voltage, and the evaluation device 7 calculates a quality of the solder joint 51 on the basis of the measurement signal.

The evaluation device 7 is used to detect and evaluate the present state (ACTUAL state) of the (aging) solder joint 51. The ACTUAL state is detected by measuring the electrical resistance of the soldering point of the transition from the solder joint 51 to the printed circuit board 2.

The evaluation of the ACTUAL state by the evaluation device 7 can take place by means of threshold values, which are permanently stored in the software algorithm or can be freely configured.

According to further embodiments, a further analog-to-digital converter can be provided, which is electrically coupled, for example, to a solder joint 52 in a further corner in order to monitor said solder joint 52. In particular, two analog-to-digital converters can be provided, which monitor the solder joints located on a diagonal in the corners. A plurality of soldering points can also be monitored by one analog-to-digital converter.

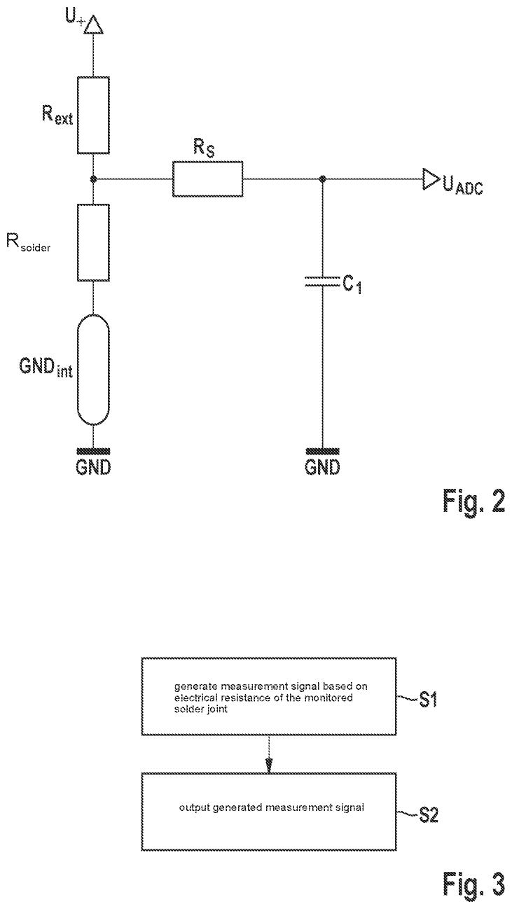

The evaluation of the solder joint 51 is explained in more detail in connection with FIG. 2. FIG. 2 shows a schematic circuit diagram of a portion of the control unit 1, in particular the voltage divider circuit used for monitoring the solder joint 51, with the supply voltage U₊. The sensed solder joint 51 is represented by the resistance R_{solder}, While Rₑₓₜ represents the external resistance of the voltage divider. The solder joint 51 is internally connected to the component-internal ground GNDᵢₙₜ via the interposer 8 or the internal bonds. The signal voltage U_{ADC} detected by the analog-to-digital converter 6 is provided by connecting a current limiting resistor Rₛ and a low-pass capacitor C₁.

In packages 3 having many contact points, the solder joints 51, 52 are generally designed as electrical ground pins at the corners of the package 3. Only the control unit GND should thus be connected there. In this embodiment of the circuit, the relevant solder joints 51, 52 are not soldered directly to the control unit GND of the printed circuit board 2 but only connected inward, either directly via bonds or the interposer 8, to the electronic circuit 4 to the circuit-side ground potential GNDᵢₙₜ. This special feature of the circuit takes advantage of the fact that further solder joints 53 are connected to the same 10 Substitute Specification ground potential and the solder joints 51, 52 located at the corners are redundant with respect to ground, i.e., do not fulfill a functional task.

The resistor divider causes an electrical voltage U_{ADC} at the input of the analog-to-digital converter 6, which electrical voltage is determined by the resistance R_{solder} of the solder joint 51. The aging of the solder joint 51 is a function of the resistance R_{solder} of the solder joint 51 and can therefore be determined therefrom.

The solder joints 5, but not 51, 52, provide the actual connection of the circuit ground GNDᵢₙₜ to the control unit ground. With the aid of this internal ground connection, a usable voltage divider can be produced for the solder joint 51.

The voltage divider is supplied with DC voltage via the terminal U₊. Ideally, the reference voltage of the analog-to-digital converter 6 is selected for U₊. Typical values are in the range between 3 V to 5 V. Alternatively, the supply voltage U₊ of the voltage divider can be pulsed in order to be able to set higher current values via the external resistance Rₑₓₜ for optimized crack detection or in order to prevent electrochemical migration. The external resistance Rₑₓₜ allows adaptation of the circuit to the expected resistance of the aging solder joint 51 and of the signal evaluation. The current limiting resistor R-ₛ protects the internal circuit of the analog-to-digital converter 6 and forms a filter with the low-pass capacitor C₁, which filter reduces signal noise.

The voltage U_{ADC} of the voltage divider corresponding to the soldering point aging is ascertained by the analog-to-digital converter 6. The evaluation of the measurement signal can be realized with the help of software.

The algorithm that reads the corresponding analog-to-digital converter channel can in principle be executed initially or permanently. An initial reading takes place, for example, shortly after the control unit 1 is switched on. Permanent reading of the analog-to-digital converter channel can take place in a loop.

The voltage U_{ADC}, which drops across the solder joint 51 and is measured by means of the analog-to-digital converter 6, is given by

$${U}_{A D C} = \frac{{R}_{s o l d e r}}{{R}_{s o l d e r} + {R}_{ext}} {U}_{+}$$

where R_{solder} is the electrical resistance of the solder joint and Rₑₓₜ is the external resistance. The parasitic resistances Rₚ of the interposer and bond connections are negligible here, assuming that Rₚ<<Rₑₓₜ is given.

By changing the equation, the resistance R_{solder} of the solder joint for the signal evaluation is obtained as

$${R}_{s o l d e r} = \frac{{U}_{A D C}}{{U}_{+} - {U}_{A D C}} {R}_{ext}$$

and is thus determined via the (digital) voltage value U_{ADC} measured by the analog-to-digital converter 6.

The value range of U_{ADC} depends on the resolution of the analog-to-digital converter 6. Resolutions of typical analog-to-digital converters 6 of 8, 10 or 12 bits result in value ranges between 0000h and 00FFh, 03FFh or 0FFFh.

A good solder joint 51 will produce a voltage value U_{ADC} close to or equal to zero. According to the voltage divider, the value of a bad (aged) solder joint 51 is correspondingly higher. For the latter value, corresponding thresholds are configured in the software.

For example, for a 10-bit analog-to-digital converter 6, the quality of the solder joint 51 can be determined as follows: If a value less than or equal to 000Fh is output, a good solder joint can be assumed. If a value between 0100h and 0200h is output, a solder joint that is already aging can be assumed. If a value between 02B0h and 0320h is output, a solder joint that is already heavily aging can be assumed. If a value between 03B0h and 03FFh is output, a solder joint that has been destroyed can be assumed.

The values mentioned above are to be understood merely by way of example and can in particular depend on the profile of the resistance R_{solder} of the solder joint 51 as a function of the aging time and on the choice of the external resistance Rₑₓₜ.

The above-mentioned relationships and the configuration of the aging stages as a function of the resistance R_{solder} of the solder joint 51 measured by means of the analog-to-digital converter 6 can be mapped via a simple software algorithm. The software can be executed as an evaluation device 7 via an ECU-internal microcontroller, and the result of the evaluation can be made available for further processing via corresponding output signals.

FIG. 3 shows a flowchart of a method for monitoring at least one solder joint of an electronic control unit, in particular of the control unit 1 described above. The electronic control unit 1 comprises a printed circuit board 2 and a package 3 having an electronic circuit 4, wherein, by means of a plurality of solder joints 5, the package 3 is arranged on the printed circuit board 2 and electrically coupled to the printed circuit board 2, and wherein at least one analog-to-digital converter 7 is electrically coupled to at least one solder joint 5.

In a step S1, the at least one analog-to-digital converter 6 generates a measurement signal (for example a voltage signal U_{ADC}) on the basis of an electrical resistance R_{solder} of the 10 monitored solder joint 51.

In a step S2, the generated measurement signal is output.

Furthermore, it can be provided that a quality of the solder joint 51 is calculated.

1-10. (canceled)

11. An electronic control unit, comprising:
a printed circuit board;
a package including an electronic circuit, wherein, using a plurality of solder joints, the package is arranged on the printed circuit board and electrically coupled to the printed circuit board; and
at least one analog-to-digital converter which is electrically coupled to at least one of the solder joints and is configured to generate a measurement signal based on the an electrical resistance of the at least one electrically coupled solder joint.

12. The electronic control unit according to claim 11, further comprising:
an external resistance, to which a reference potential is applied, wherein the external resistance is connected in series with the electrical resistance of the at least one of the solder joints to provide a voltage divider.

13. The electronic control unit according to claim 11, further comprising:
an evaluation device configured to calculate a quality of the at least one of the solder joints based on the measurement signal.

14. The electronic control unit according to claim 13, wherein the evaluation device calculates the quality based on an at least three-stage scale.

15. The electronic control unit according to claim 11, wherein the plurality of solder joints are solder balls or solder pins.

16. The electronic control unit according to claim 11, wherein the plurality of solder joints is arranged on a rectangular base, and wherein the at least one analog-to-digital converter is electrically coupled to at least one of the solder joints in a corner of the rectangular base.

17. The electronic control unit according to claim 16, wherein a first analog-to-digital converter is electrically coupled to a first solder joint, and a second analog-to-digital converter is electrically coupled to a second solder joint, wherein the first solder joint and the second solder joint are located on a diagonal of the rectangular base.

18. The electronic control unit according to claim 11, wherein the electronic circuit is a microcontroller or an application-specific circuit (ASIC).

19. The electronic control unit according to claim 11, wherein the electronic circuit is connected to the plurality of solder joints via an interposer.

20. A method for monitoring at least one solder joint of an electronic control unit, wherein the electronic control unit includes a printed circuit board and a package having an electronic circuit, wherein, using a plurality of solder joints, the package is arranged on the printed circuit board and electrically coupled to the printed circuit board, and wherein at least one analog-to-digital converter is electrically coupled to at least one of the solder joints, wherein the method comprises the following steps:
generating, using the at least one analog-to-digital converter, a measurement signal based on an electrical resistance of the at least one of the solder joints electrically coupled to the analog-to-digital converter; and
outputting the generated measurement signal.
